(19) United States
(12) Patent Application Publication
(10) Pub. No.: US 2008/0205120 A1
(43) Pub. Date: Aug. 28, 2008

(54) Multiple layer random accessing memory

(76) Inventor: Chih-Ta Star Sung, Glonn (DE)

Correspondence Address: Chih-Ta Star Sung, Rm. 308, Bld. 52, No. 195, Sec. 4, Chung Hsin Rd., Juhdong, 310, omitted

(21) Appl. No.: 11/710,059

(22) Filed: Feb. 23, 2007

(51) Int. Cl. G11C 11/24

(52) U.S. Cl. 365/149

(57) ABSTRACT

The present invention provides a new semiconductor Random Access Memory, RAM which stores multiple bits per cell. When writing data, at least three levels of voltage sources are generated to charge the bit line and the RAM capacitive device through the selective devices. During reading data, at least three referencing voltage sources are input to at least three sense amplifiers to differentiate at least four levels of bit line voltages and convert the differential levels to at least two logic bits.

### BACKGROUND OF THE INVENTION

1. Field of Invention

This invention relates generally to a semiconductor RAM, a Random Accessing Memory. In particular, it relates to a RAM cell and its related writing and sensing scheme for accessing which can store multiple bits per cell.

2. Description of Related Art

A semiconductor random access memory chip is typically comprised of an array of memory cells which are aligned in rows and columns and peripheral circuitry. A memory cell is used to store data for future use. For area efficiency, a memory array includes a large amount of memory cells, a word line, WL runs across top of hundreds or even thousands of memory cell gates which makes the WL capacitance load quite large and needs a big driver to accelerating the speed of charging up the capacitive load of memory cells hooked to the same word line.

The Random Access Memory, RAM, using a capacitor 12 as the storage device has advantages of small cell size and reasonable high speed in writing data and reading data. Therefore costs least price per unit to manufacture compared to its counter parts other memories like SRAM or some Non-Volatile Memories, NVM including flash or EPROM memories, and DRAM becomes the main storage device in many applications. A RAM cell as shown in FIG. 1 is commonly comprised of an N-type device 11 with a fixed channel width and length as the pass transistor. The gate of the pass transistor of the RAM cell is hooked to a world line 10 while another node of diffusion, so named as “drain” is hooked into a so named “bit line” 13 and the other node of diffusion is connected to a capacitor with the other return node grounded.

The prior art of the RAM design mainly is comprised of a cell with a fixed pass transistor and a cell which can store one bit per cell. This invention of the multiple levels RAM can store at least two bits per cell sharply making the efficiency of storage higher.

### SUMMARY OF THE INVENTION

The present invention of an MLC RAM, Multiple Layer Cell Random Access Memory increases the data density per cell. The present invention of the MLC RAM stores more than 1 bit per cell by applying multiple levels of voltage to, said the bit line and be transferred to the RAM cell when writing.

According to an embodiment of this invention of the MLC RAM, the RAM cell is comprised of an N-type MOS device as the pass transistor and a capacitor as a storage being able to save at least four electrical levels representing at least two bits by a single cell.

According to an embodiment of this invention of the MLC RAM, when writing the data into the RAM cell, at least four levels of voltage are able to be transferred to the selected RAM cell when writing.

According to an embodiment of this invention of the MLC RAM, multiple referencing voltages are applied to differentiate multiple levels of the bit line voltage which input to sense amplifies during reading.

According to an embodiment of the present invention of the MLC RAM, at least four predetermined states are determined for four corresponding voltage levels to be transferred into the RAM cell which is comprised of a capacitor.

According to another embodiment of this invention of the MLC RAM, for gaining higher reliability and hence the yield, a back biasing circuit is applied to reduce the leak current and hence help in keeping the margin between logic states.

According to another embodiment of this invention of the MLC RAM, at least two levels of voltage are generated by charge pump circuit.

Other aspects and advantages of the present invention will become apparent from the following detailed description, taken in conjunction with the accompanying drawings, illustrating by way of example the principles of the invention. It is to be understood that both the foregoing general description and the following detailed description are by examples, and are intended to provide further explanation of the invention as claimed.

### BRIEF DESCRIPTION OF THE DRAWINGS

FIG. 1A depicts the commonly used DRAM cell with one pass transistor and a capacitor.

FIG. 1B depicts the prior art DRAM memory array and accessing scheme, a simplified block diagram of a memory bank comprising a word line decoder, a word line driver, an array of ROM cells, a sense amplifier and a column decoder.

FIG. 2 depicts timing of how a memory cell data accessing of a prior art sensing scheme. When the bit line voltage crosses the reference voltage, sense amplifier switches the state.

FIG. 3 describes the a simplified block diagram of the sensing scheme of a memory cell.

FIG. 4 depicts the present invention of the MLC RAM memory with a bit line being charged to potential three levels of power or to ground and the pass transistor can pass the selected level to the RAM cell which is a capacitor.

FIG. 5 depicts the differencing of bit line voltage which demonstrates the concept of differentiating the four levels of bit line voltage when accessing the DRAM memory cell.

FIG. 6 illustrates the mechanism of how the multiple levels of power suppliers and bit line is generated including charge pumps or DC voltages.

FIG. 7 illustrates a scheme of one charge pump circuit being shared by multiple bit lines.

### DESCRIPTION OF THE PREFERRED EMBODIMENTS

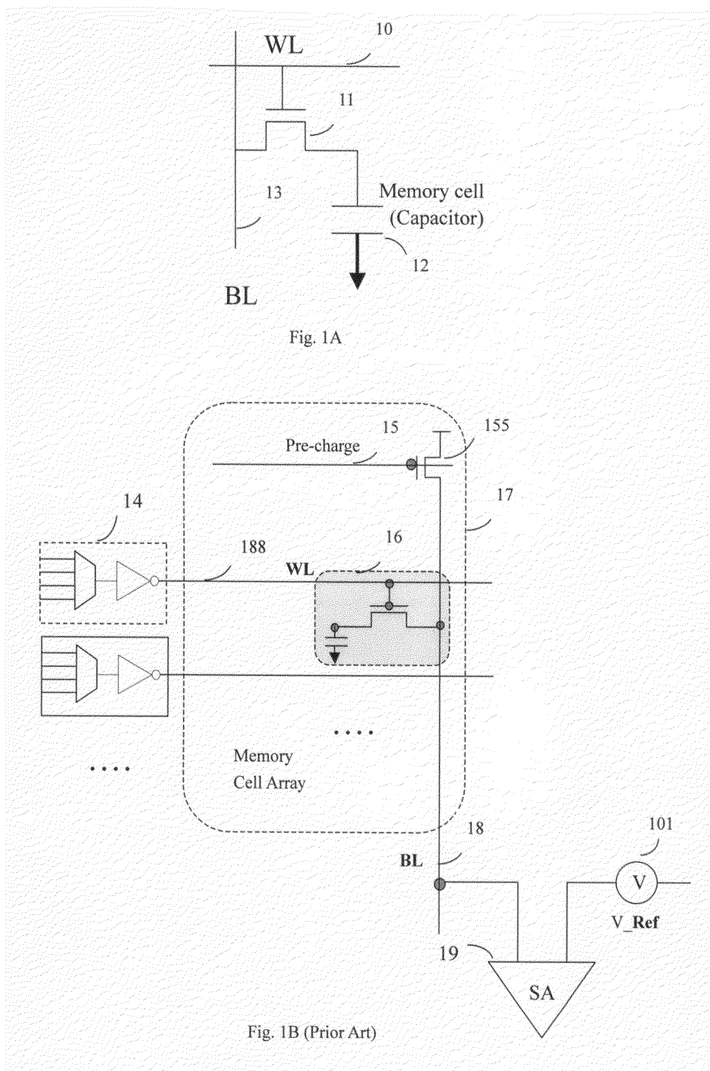

The semiconductor Random Access Memory, RAM has advantages of small cell size and fast accessing with reasonable low power consumption in reading and writing data and therefore costs least price to manufacture compared to its counter parts memories like Non-Volatile Memories, NVM including flash or EPROM memories. A commonly used dynamic RAM cell as shown in FIG. 1 is comprised of an N-type device 11 with a fixed channel width and length as the pass transistor. The gate of the pass transistor of the RAM cell is hooked to a world line 10 while another node of diffusion, so named as “drain” is hooked into a so named “bit line” 13 and the other node of diffusion is connected to a capacitor with the other return node grounded.

FIG. 1B illustrates the simplified accessing scheme of the prior art of RAM memory which has limitation of 1 bit per cell. For area efficiency, a memory array 17 is comprised of a large amount of memory cells. In a memory array, there are a large amount of cells connect to the same column node which has a term of said “bit line” 18 through the pass transistor's drain node. While another large amount of cells are hooked up to a row node, or so named “word line” 188 through the pass transistor's gate node. The bit line is pre-charged 15 to a predetermined voltage level through a MOS transistor 155. The row address decoder 14 translates the address and selects the corresponding row of memory cells to be accessed either for writing new data or reading out the cell data. A sense amplifier 19 with two input nodes, one from the bit line, and another node from a referencing voltage 101 sense the bit line voltage and amplifies it to be able to represent a logic bit of “0” (Ground) or “1” (Vdd).

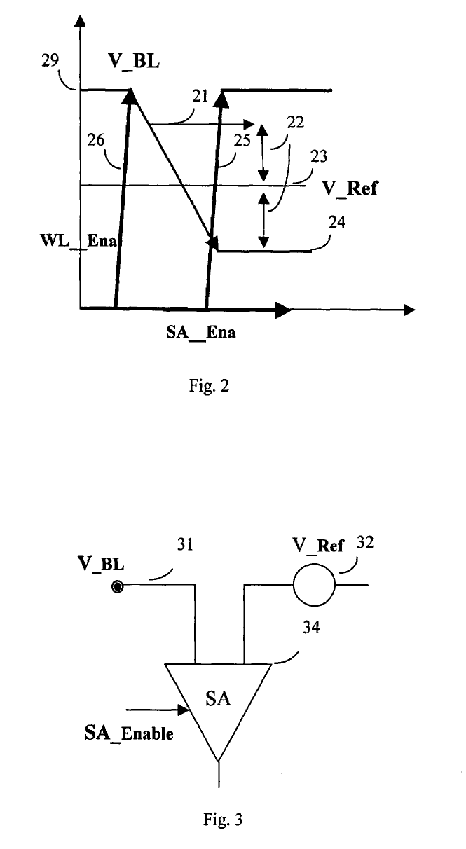

FIG. 2 depicts the conceptual feature of the sensing scheme of reading out the data from the prior art RAM cell. A bit line is pre-charged 29 to a predetermined voltage level, said Vdd when non-accessing cycle. During accessing, the selected word line enables 26 the memory cell through the gate of the pass transistor and the capacitive device starts discharging the bit line by the mechanism so called “charge sharing” since the bit line is in higher voltage level and the capacitive device will be in lower level either it was charged to Vdd or grounded. If the capacitive device is charged to Vdd, the charge will be leaked through a parasitic path to the substrate and the voltage will be lower than Vdd level and after charge sharing, the bit line voltage will be pulled in some degree lower than Vdd level 21 but still higher than a referencing voltage 23. If the RAM capacitive device is grounded, then, the bit line will be pulled even lower 24 than the referencing voltage before the sense amplifier is enabled 25. The timing of enabling the sense amplifier is mostly determined by the margin levels 22 of differentiating the bit line and the referencing voltage 23. FIG. 3 simplifies the sense amplifier circuit with two input nodes to the sense amplifier 34, one node is coupled to the bit line 31 and the other node to the referencing voltage supplier 32 which can be generated by external DC voltage or internal circuit.

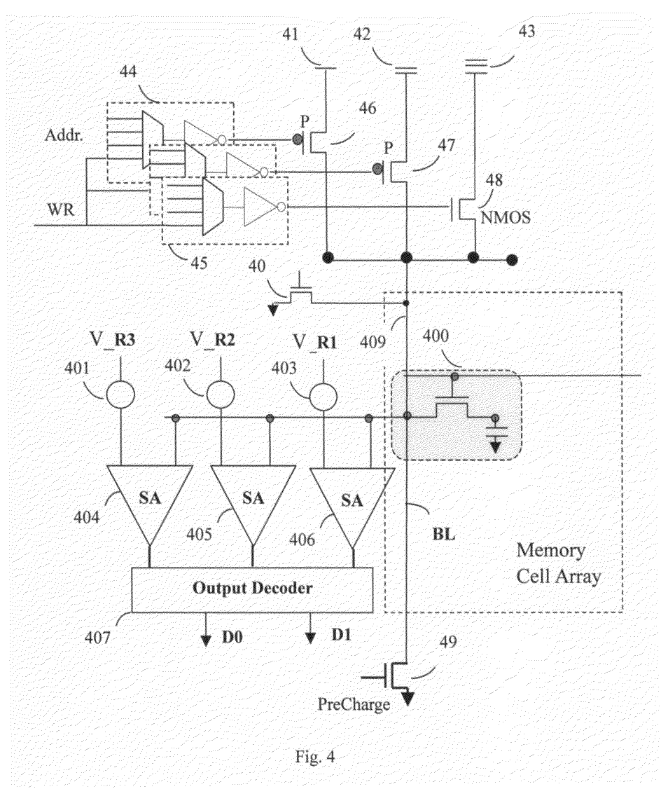

FIG. 4 illustrates this invention of the multiple layer cell RAM. A bit line 409 is connected to at least three voltage suppliers 41, 42, 43 and the ground through selecting at least four devices 46, 47, 48, 40 (the one connecting to “ground”). The address decoder 44, 45 for selecting the corresponding row of the RAM cells 408 also drive the word line load capacitor. During writing cycle, for instance, writing two bit into a RAM cell 400, one of the predetermined said four levels of voltages will be connect to charge or discharge the bit line node to a predetermined level. For instance, the four levels of voltage are Vdd, ⅔ Vdd, ⅓ Vdd and ground standing for “00”, “01”, “10” and “11” states. During reading the RAM cell data, at least three referencing voltages 401, 402, 403 are connected to at least three sense amplifiers 404, 405, 406 with another node of each sense amplifier connecting to the bit line 409. The four bit line levels can be differentiated by the three referencing voltage and three sense amplifiers. When in non-accessing cycle, the bit line is pulled down to a predetermined voltage level, said “Ground”, through a pull-down device 49. After reading, the corresponding bits will be written back to the RAM cell with the corresponding voltage level.

Since an N-type semiconductor device can pass lower voltage with higher efficiency than a P-type device, the pass transistor connecting the lower level of supplier voltage to the RAM cell is made by an N-type MOS device and the other two pass transistors connecting the higher levels of supplier voltage to the RAM cell is made by P-type MOS devices.

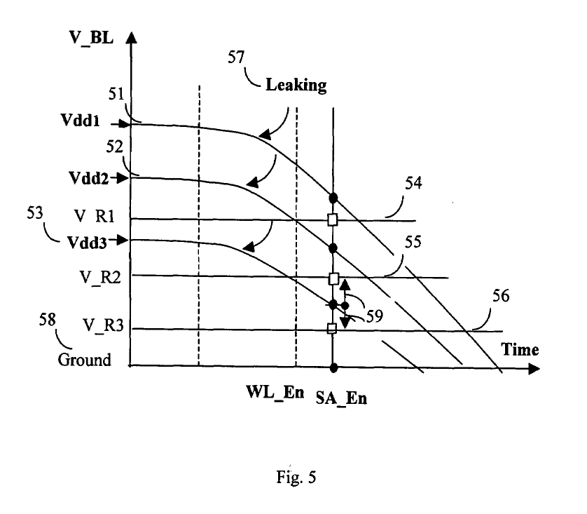

FIG. 5 illustrates the conceptual sensing scheme of this invention of the multiple layer cell RAM. An RAM cell might be charged to one of the multiple levels of voltage (for example, Ground=0V, Vdd1=3V, Vdd2=2V, Vdd3=1V) 58, 51, 52, 53. And three referencing voltages (for example, V_R1=2.5V, V_R2=1.5V, V_R2=0.5V) 54, 55, 56 are input to three sense amplifiers to differentiate the four levels of the input signal from the bit line which is the charge sharing result of the RAM cell and the bit line capacitive load. For gaining best performance and yield, any of the referencing voltages to the corresponding nearest bit line voltage levels are adjusted to be approximately equal 59.

The four levels of one single RAM cell voltages can be identified as 2 bits. More levels can also be applied to charge the RAM cell capacitive device to represent more bits. For instance, 8 levels can represent 3 bits. Practically, a RAM cell will have parasitic junction diode formed by the N+ diffusion and the P-type substrate which leaks current 57 and will pull the capacitive device voltage lower overtime, and the common solution to avoid leak current cause mistake of sensing is to “Refresh” the RAM cell the time before the capacitive device voltage is pulled down to make potential wrong sensing data.

In this invention of the multiple layer cell RAM, two solutions are proposed to minimize the leak current. The first solution is to refresh the capacitive device in a shorter duration by reading out the data and writing back the voltage level according to the readout data of logic bits. Another solution is to provide the a back biased negative to avoid turning on the parasitic P-N junction diode of the leak path. The later can also be realized by a negative voltage supplier pin or internally generated negative voltage by a charge pump circuit.

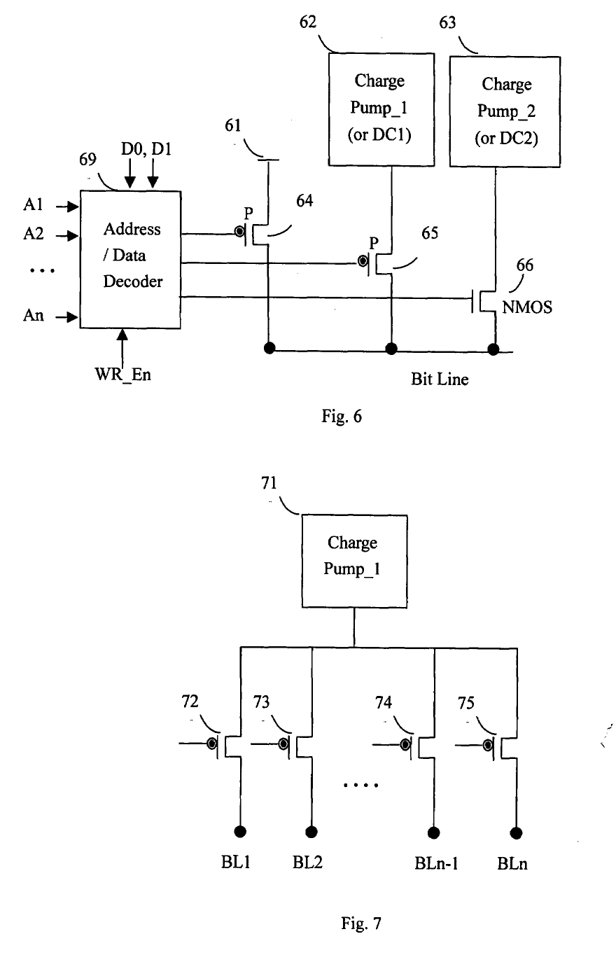

Since applying multiple power suppliers from external pins might not be available, using charge pump circuit internally generating multiple levels of voltage as the supply of the bit line and the RAM cell capacitive device becomes a good choice. FIG. 6 illustrates the selected solution of multiple levels of voltage suppliers 61, 62, 63 connecting to a bit line node including two charge pumps 62, 63 for generating two other level of voltage supply. The power suppliers generated by internal charge pumps or external power pin are connected to the bit line node through the P-type pass transistors 64, 65, 66. An address/data decoder circuit 69 determines which bit is to be accessed and If in write cycle, which level of voltages is going to be applied to the bit line and RAM cell.

The charge pump circuit comprising some sensitive analog circuits, costs a large die area and power consumption. For efficiency, a charge pump circuit 71 can provide voltage to multiple bit lines, and only one of the selected bit line will be charged at a time as shown in FIG. 7. the generated voltage is connected to multiple bit lines through the selected P-type devices 72, 73, 74, 75.

Some logic function can be integrated together into this invention of the multiple layer cell RAM and this RAM memory serves as an cashing buffer for data or/and image storage.

It will be apparent to those skills in the art that various modifications and variations can be made to the structure of the present invention without departing from the scope or the spirit of the invention. In the view of the foregoing, it is intended that the present invention cover modifications and variations of this invention provided they fall within the scope of the following claims and their equivalents.

What is claimed is:

1. A semiconductor Random Access Memory, which an RAM cell can store at least two bits, comprising:
an RAM cell which is made of a capacitive device connected to two nodes, the ground and the bit line through an MOS pass transistor;
At least three selecting devices connecting each bit line node to at least four levels of voltage sources which can be from external voltage suppliers or be generated by charge pump circuits;
when writing data, the selected level of voltage charges or discharges the RAM cell capacitive device and the bit line through the selecting pass transistor; and
when reading data, at least three sense amplifiers are turned on to sense the bit line voltage levels and converted the levels into at least two logic bits.

2. The bit line pre-charging scheme in the RAM cell as recited in claim 1, wherein a pull-down device is controlled by a pre-charging signal and pulls the bit line node down to a predetermined level of voltage during non-accessing period.

3. The RAM memory cell as recited in claim 1, wherein the storage feature is made feasible by using a capacitive device to keep charge of supplier voltage.

4. The address and data decoder in claim 1, wherein the address decoder determines the location of RAM cell to be accessed and the data decoder decides which level of voltage suppliers to be connected to charge the selected RAM cell during writing.

5. The charge pump circuit in claim 1, wherein a charge pump can be connected to at least two adjacent bit lines to charge the selected RAM cells.

6. The RAM memory cell as recited in claim 1, wherein the RAM cells will be periodically read out to check the voltage level and its corresponding logic status and the corresponding level of voltage will charge the RAM cell to avoid the voltage level being dropped down to a level which ambiguity of logic level might happy.

7. The pass transistors connecting the bit line to supply voltages as recited in claim 1, wherein, they are made of P-type semiconductor device for which conducting the bit line to the predetermined level of voltage higher than another threshold value.

8. The pass transistors connecting the bit line to supply voltages as recited in claim 1, wherein, they are made of N-type semiconductor device for which conducting the bit line to the predetermined level of voltage lower than another threshold value.

9. A sensing scheme for reading out the multiple bits within an RAM cell within the semiconductor Random Access Memory, RAM, comprising:
a charge pump circuit generating a negative voltage to be connect to the substrate of the RAM to back bias the substrate and minimize the leak current of the parasitic junction diode of the pass transistor;
at least three referencing voltage sources input to at least three sense amplifiers to differentiate at least four levels of bit line voltages;
a timing control engine to decide an appropriate timing to enable the sense amplifiers output signals; and
after reading out the RAM cell signal, the corresponding bits are written back to the RAM cell.

10. The sense amplifier circuit as recited in claim 9, wherein the sense amplifier has two input nodes with one connected to the bit line and the other node connected to the node of referencing voltage supplier.

11. The referencing voltage generator circuit as recited in claim 9, wherein after RAM cell is turned on, each of the referencing voltages to the corresponding nearest two bit line voltages are predetermined to be approximately equal.

12. The writing back mechanism as recited in claim 9, wherein after RAM cell is read out, the corresponding bits are written back to the RAM cells through regular writing path.
